(19) United States
(12) Patent Application Publication
(10) Pub. No.: US 2026/0082670 A1
(43) Pub. Date: Mar. 19, 2026

(54) SEMICONDUCTOR DEVICE

(71) Applicant: Kioxia Corporation, Tokyo (JP)

(72) Inventors: Yuya OMURA, Yokkaichi Mie (JP); Hiroki OKAMOTO, Kuwana Mie (JP)

(21) Appl. No.: 19/066,422

(22) Filed: Feb. 28, 2025

(30) Foreign Application Priority Data
Sep. 18, 2024 (JP) 2024-161250

(51) Int. Cl. H10D 64/66; H01L 23/00; H01L 25/065; H10B 41/35; H10B 43/35; H10B 80/00

(52) U.S. Cl. CPC H10D 64/668; H10B 41/35; H10B 43/35; H10B 80/00; H10W 90/00; H10W 90/20; H10W 90/794

(57) ABSTRACT

A semiconductor device includes a first transistor and a second transistor. The first transistor includes: a first diffusion layer region and a second diffusion layer region; a first gate insulating film and including a portion between the first diffusion layer region and the second diffusion layer region; and a first gate electrode positioned over the first gate insulating film. The second transistor includes: a third diffusion layer region and a fourth diffusion layer region; a second gate insulating film and including a portion between the third diffusion layer region and the fourth diffusion layer region; and a second gate electrode positioned over the second gate insulating film. At least one of the first transistor or the second transistor is formed in a recess portion that has a bottom surface at a position lower than an upper surface of the device isolation portion.

### CROSS-REFERENCE TO RELATED APPLICATION

This application is based upon and claims the benefit of priority from Japanese Patent Application No. 2024-161250, filed Sep. 18, 2024, the entire contents of which are incorporated herein by reference.

### FIELD

Embodiments described herein relate generally to a semiconductor device.

### BACKGROUND

A semiconductor device including a semiconductor substrate and a plurality of transistors provided on the semiconductor substrate is known. Further, a semiconductor device is known that includes two types of transistors: a high voltage transistor that operates at a relatively high voltage and a low voltage transistor that operates at a relatively low voltage.

### DESCRIPTION OF THE DRAWINGS

FIG. 1 is a cross-sectional view showing a configuration example of a semiconductor device of a first embodiment.

FIG. 2 is a cross-sectional view showing a configuration example of a semiconductor substrate and a low voltage transistor and a high voltage transistor applied to the semiconductor device of the first embodiment.

FIG. 3 is a plan view showing a positional relation between a source region and a drain region and a silicide layer of the low voltage transistor according to the first embodiment.

FIG. 4 is a cross-sectional view showing a configuration example of the semiconductor substrate and the low voltage transistor according to the first embodiment.

FIG. 5 is a plan view showing a positional relation between the source region and the drain region and the silicide layer of the high voltage transistor according to the first embodiment.

FIG. 6 is a cross-sectional view showing a configuration example of the semiconductor substrate and the high voltage transistor according to the first embodiment.

FIG. 7 is a plan view showing a positional relation between a source region and a drain region and a silicide layer of a low voltage transistor according to Comparative Example 1.

FIG. 8 is a cross-sectional view showing a configuration example of the semiconductor substrate and the low voltage transistor according to Comparative Example 1.

FIG. 9 is a plan view showing a positional relation between a source region and a drain region and a silicide layer of a high voltage transistor according to Comparative Example 1.

FIG. 10 is a cross-sectional view showing a configuration example of the semiconductor substrate and the high voltage transistor according to Comparative Example 1.

FIG. 11 is a plan view showing a positional relation between a source region and a drain region and a silicide layer of a low voltage transistor according to a Comparative Example 2.

FIG. 12 is a cross-sectional view showing a configuration example of the semiconductor substrate and the low voltage transistor according to Comparative Example 2.

FIG. 13 is a plan view showing a positional relation between a source region and a drain region and a silicide layer of a high voltage transistor according to Comparative Example 2.

FIG. 14 is a cross-sectional view showing a configuration example of the semiconductor substrate and the high voltage transistor according to Comparative Example 2.

FIG. 15 is a cross-sectional view showing a related transistor structure.

FIG. 16 is a cross-sectional view showing the problems encountered when manufacturing the related transistor structure.

FIG. 17 is a cross-sectional view showing a configuration example of a semiconductor substrate and a low voltage transistor and a high voltage transistor according to a second embodiment.

FIG. 18 is a cross-sectional view illustrating a method of manufacturing the semiconductor device according to the first embodiment.

FIG. 19 is a cross-sectional view illustrating the method of manufacturing the semiconductor device according to the first embodiment.

FIG. 20 is a cross-sectional view illustrating the method of manufacturing the semiconductor device according to the first embodiment.

FIG. 21 is a cross-sectional view illustrating the method of manufacturing the semiconductor device according to the first embodiment.

FIG. 22 is a cross-sectional view illustrating the method of manufacturing the semiconductor device according to the first embodiment.

FIG. 23 is a cross-sectional view illustrating the method of manufacturing the semiconductor device according to the first embodiment.

### DETAILED DESCRIPTION

Embodiments provide a semiconductor device capable of improving the on-current of a low voltage transistor and reducing the junction leakage current of a high voltage transistor.

In general, according to one embodiment, a semiconductor device includes a semiconductor substrate, a first transistor, a second transistor, and a device isolation portion embedded in the semiconductor substrate to isolate the first transistor and the second transistor. The first transistor includes: a first diffusion layer region and a second diffusion layer region provided on the semiconductor substrate; a first gate insulating film provided on the semiconductor substrate, and including at least a portion facing a region between the first diffusion layer region and the second diffusion layer region; a first gate electrode positioned over the first gate insulating film; and a first silicide layer embedded in an upper surface of the first diffusion layer region and a second silicide layer embedded in an upper surface of the second diffusion layer region. A second transistor includes: a third diffusion layer region and a fourth diffusion layer region provided on the semiconductor substrate; a second gate insulating film provided on the semiconductor substrate, and including at least a portion facing a region between the third diffusion layer region and the fourth diffusion layer region; a second gate electrode positioned over the second gate insulating film; and a third silicide layer embedded in an upper surface of the third diffusion layer region and a fourth silicide layer embedded in an upper surface of the fourth diffusion layer region. At least one of the first transistor or the second transistor is formed in a recess portion that has a bottom surface at a position lower than an upper surface of the device isolation portion.

Hereinafter, a semiconductor device according to the embodiments will be described with reference to the drawings. In the following description, configurations having the same or similar functions are designated by the same reference numerals. Then, the duplicate description of those configurations may be omitted. Terms “parallel”, “orthogonal”, or “same” may encompass “substantially parallel”, “substantially orthogonal”, or “substantially the same”, respectively. The term “connection” is not limited to mechanical connections and may include electrical connections. That is, the term “connection” is not limited to a plurality of elements being directly connected to each other, and may include a plurality of elements being connected to each other with another element interposed therebetween. The term “facing” may mean that two members overlap each other when viewed in a certain direction, and may include the case where another member exists between the two members.

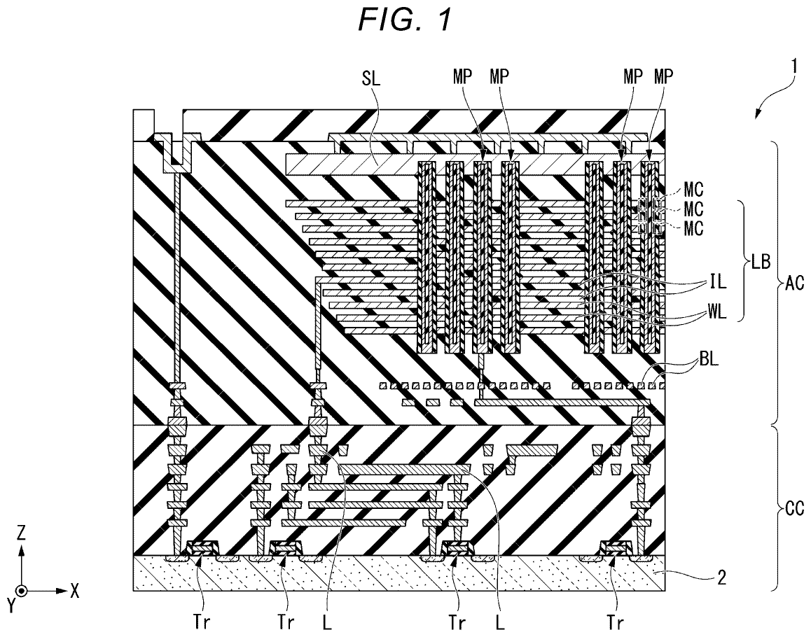

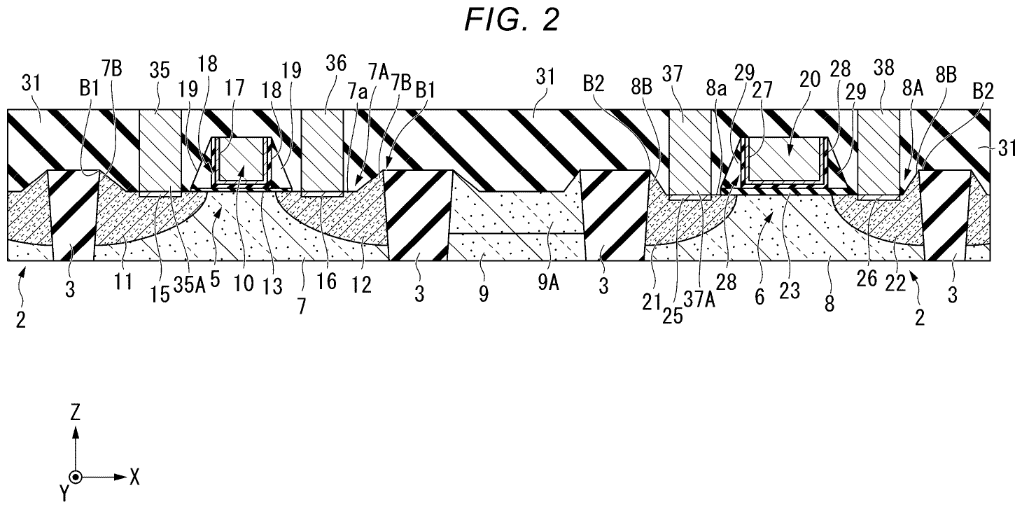

First, X direction, Y direction, and Z direction are defined. The X and Y directions are directions along the surface of a semiconductor substrate 2 which will be described below (see FIG. 1). The X direction is a direction from a first source region 11 toward a first drain region 12 in a first transistor 5 described below (see FIG. 2), and a direction from a second source region 21 toward a second drain region 22 in a second transistor 6 described below (see FIG. 2). The Y direction is a direction that intersects with (for example, orthogonal to) the X direction. The Z direction is a direction that intersects with (for example, orthogonal to) the X and Y directions. The Z direction is a thickness direction of the semiconductor substrate 2 (see FIG. 2). In the following description, the side of the semiconductor substrate 2 where a transistor Tr is positioned may be referred to as an “upper side” and the opposite side may be referred to as a “lower side”. However, these expressions are only for convenience and do not define the direction of gravity.

### First Embodiment

### 1. Configuration Example of Semiconductor Device

FIG. 1 is a cross-sectional view showing a configuration example of the semiconductor device 1 of the first embodiment. The semiconductor device 1 is a semiconductor storage device such as a NAND flash memory. The semiconductor device 1 includes, for example, an array chip AC and a circuit chip CC.

The array chip AC is a chip capable of storing information. The array chip AC includes, for example, a stack LB, a plurality of memory pillars MP, a plurality of source lines SL, and a plurality of bit lines BL. The stack LB includes a plurality of word lines WL and a plurality of insulating layers IL. The plurality of word lines WL and the plurality of insulating layers IL are alternately stacked one by one in the Z direction.

The plurality of memory pillars MP extend through the stack LB in the Z direction. Each of the plurality of memory pillars MP includes an insulating portion, a channel layer, a tunnel insulating film, a charge storage portion, and a block insulating film, in a direction from a center of the memory pillar MP toward an outer peripheral side. One end of each memory pillar MP is connected to the source line SL. The other end part of each memory pillar MP is connected to the bit line BL. A memory cell transistor MC is formed at an intersection of each memory pillar MP and each word line WL. The memory cell transistor MC is a storage element capable of storing information by accumulating electric charges.

The circuit chip CC is a control circuit for controlling the operation of the array chip AC. The circuit chip CC includes, for example, the semiconductor substrate 2, a plurality of transistors Tr, and a plurality of wiring lines L. The plurality of transistors Tr are provided on the semiconductor substrate 2. The wiring lines L connect the transistors Tr to the array chip AC.

### 2. Configuration of Semiconductor Substrate and Transistor

Next, the configuration of the semiconductor substrate 2 and the transistor Tr is described in detail.

### 2.1 Semiconductor Substrate

FIG. 2 is a cross-sectional view showing a configuration example of the semiconductor substrate 2 and a first transistor 5 and a second transistor 6 which will be described below.

The semiconductor substrate 2 is a silicon substrate including a single crystal silicon as an example. One or more device isolation insulation regions 3 (hereinafter, referred to as “device isolation portion 3”) formed of insulators such as silicon oxides are formed in a part of an upper layer part of the semiconductor substrate 2. The device isolation portions 3 are positioned along the X direction with the first transistor 5 and the second transistor 6 disposed therebetween, respectively. The semiconductor substrate 2 includes a first substrate portion 7 and a second substrate portion 8 isolated from each other in the X direction through two adjacent device isolation portions 3. The first transistor 5 is formed on the first substrate portion 7, and the second transistor 6 is formed on the second substrate portion 8. In addition, the cross-section in FIG. 2 shows only the upper layer region close to the surface of the semiconductor substrate 2, and the device isolation portion 3 is formed to a predetermined depth of the semiconductor substrate 2 in a slightly downward narrowing shape from the surface of the semiconductor substrate 2 toward a depth direction (−Z direction). FIG. 2 omits the illustration of the bottom side of the device isolation portion 3 and only shows the upper side of the device isolation portions 3 and a region where the first transistor 5 and the second transistor 6 are formed between them. Further, FIG. 1 omits the illustration of the device isolation portion 3, and in FIG. 1, the first transistor 5 and the second transistor 6 are not distinguished from each other, but are simply represented as transistor Tr to show only an overview of the positional relationship of each transistor Tr.

In the semiconductor device 1 shown in FIG. 1, a structure may be adopted on the surface part of the semiconductor substrate 2 as shown in detail in FIG. 2, in which the first transistor 5 and the second transistor 6 are disposed adjacent to each other in the X direction through the device isolation portion 3.

In this embodiment, two device isolation portions 3 are spaced apart from each other in the X direction between the first transistor 5 and the second transistor 6. The device isolation portions 3 provided on both sides of the first transistor 5 in the X direction insulate and isolate a region where the first transistor 5 is formed from a surrounding region. The device isolation portions 3 provided on both sides of the second transistor 6 in the X direction insulate and isolate a region where the second transistor 6 is formed from a surrounding region.

A third substrate portion 9 is formed between the two device isolation portions 3 spaced apart from each other along the X direction between the first transistor 5 and the second transistor 6, and a diffusion layer 9A is formed in the upper part of the third substrate portion 9.

As an example, the diffusion layer 9A includes impurities such as As, P, and B and is provided for use as a resistance element.

The first substrate portion 7 and the second substrate portion 8 serve as bases for providing the transistors Tr. The first substrate portion 7 and the second substrate portion 8 include well regions having a different polarity (different conductivity type) from a source region and a drain region of the transistor Tr, which will be described below, at least in part of the region where the transistor Tr is formed.

The device isolation portion 3 is an isolation portion that electrically isolates the plurality of transistors Tr provided on the semiconductor substrate 2. The device isolation portion 3 is provided in the semiconductor substrate 2 to surround an activation region of each transistor Tr.

### 2.2 Transistor

The plurality of transistors Tr include the first transistor 5 (see FIG. 2) and the second transistor 6 (see FIG. 2). Each of the first transistor 5 and the second transistor 6 is a field effect type transistor such as, for example, a Metal-Oxide-Semiconductor-Field-Effect-Transistor (MOSFET).

The second transistor 6 is a high voltage transistor for outputting a relatively high voltage (for example, a voltage of 20 V or more), and the first transistor 5 is a low voltage transistor for outputting a relatively low voltage (for example, 10 V or less) in the semiconductor device 1. As described above, the transistor Tr shown in FIG. 1 is simply referred to as the transistor Tr without distinguishing between the first transistor 5 and the second transistor 6, and only an overview is depicted. Among the plurality of transistors Tr, some of the transistor Tr are the first transistors 5 (low voltage transistors), and some of the transistors Tr are the second transistors 6 (high voltage transistors). FIG. 2 illustrates a structure in which the first transistor 5 and the second transistor 6 are adjacent to each other along the X direction in the semiconductor substrate 2.

### First Transistor

For example, the first transistor 5 includes a first gate electrode 10, the first source region 11, the first drain region 12, a first gate insulating film 13, a first diffusion layer side silicide layer 15 (hereinafter, simply referred to as a first silicide layer), a second diffusion layer side silicide layer 16 (hereinafter, simply referred to as a second silicide layer), a work function metal layer 17, a ferroelectric layer 18, and an insulating sidewall 19. The first source region 11 is an example of the “first diffusion layer region”. The first drain region 12 is an example of the “second diffusion layer region”. However, the first drain region 12 may correspond to an example of the “first diffusion layer region”, and the first source region 11 may correspond to an example of the “second diffusion layer region”.

The first transistor 5 is provided between the device isolation portions 3 and 3 formed on both sides of the first transistor 5 in the X direction. A recess portion 7A (first recess portion) is formed on the upper surface of the first substrate portion 7 between two device isolation portions 3 adjacent to each other in the X direction. The recess portion 7A is formed such that its bottom surface 7a is one step lower than an upper surface of the device isolation portion 3. An inclined portion 7B, which gradually makes the depth of the recess portion 7A shallow, is formed at a part adjacent to the device isolation portion 3 in the recess portion 7A. A top of the inclined portion 7B is positioned at substantially the same height as the upper surface of the device isolation portion 3, and the top of the inclined portion 7B is continuous with the upper surface of the device isolation portion 3. A portion where the top of the inclined portion 7B contacts the upper surface of the device isolation portion 3 is an interface position B1 between the surface of the semiconductor substrate 2 and the device isolation portion 3. The recess portion 7A may be described herein as a recess portion including the bottom surface 7a lower than the interface position B1 in the Z direction.

As shown in FIG. 2, the first gate insulating film 13 with a predetermined width in the X direction is disposed on a central side of the bottom surface 7a (surface of the first substrate portion 7) of the recess portion 7A. The first silicide layer 15 and the second silicide layer 16 are positioned on both sides along the X direction. In addition, a first contact electrode 35 connected to the first silicide layer 15 is provided, and a second contact electrode 36 connected to the second silicide layer 16 is provided.

The first gate electrode 10 is provided on the opposite side of the semiconductor substrate 2 relative to the first gate insulating film 13 to be described below. The first gate electrode 10 is positioned above the bottom surface 7a of the recess portion 7A in the first substrate portion 7. The first gate electrode 10 is positioned between the first source region 11 and the first drain region 12 in the X direction. As an example, the first gate electrode 10 may be formed of a metal such as tungsten, but it may also be a semiconductor layer such as polysilicon or a stacked structure of the semiconductor layer and the metal layer.

The first source region 11 and the first drain region 12 are formed at a predetermined depth as part of the bottom surface 7a of the recess portion 7A in the first substrate portion 7. For example, the first source region 11 and the first drain region 12 are formed by doping impurities into the upper portion of the first substrate portion 7 (e.g., the bottom surface 7a and the inclined portion 7B of the recess portion 7A). The first source region 11 and the first drain region 12 are isolated from each other in the X direction. The first gate insulating film 13 is provided on the bottom surface 7a of the recess portion 7A of the first substrate portion 7 between the first source region 11 and the first drain region 12 spaced apart from each other in the X direction. In this embodiment, each of the first source region 11 and the first drain region 12 includes an n⁺-type semiconductor or a p-type semiconductor (for example, a p⁺-type semiconductor).

A depth (depth along the Z direction) of the recess portion 7A is about 1/10 to 2/10 of the maximum depth (maximum depth along the Z direction) of the first source region 11 or the first drain region 12. For example, if the maximum depth of the first source region 11 is about 100 nm, the depth of the recess portion 7A may be about 10 to 20 nm.

The first gate insulating film 13 is formed on the bottom surface 7a of the recess portion 7A in the first substrate portion 7. At least a portion of the first gate insulating film 13 is positioned between the first gate electrode 10 and the bottom surface 7a of the recess portion 7A. The first gate insulating film 13 is formed, for example, by a silicon oxide film. In this embodiment, the thickness of the first gate insulating film 13 in the Z direction is less than the thickness of a second gate insulating film 23 described below in the Z direction. A maximum voltage of a current flowing through the first transistor 5 is less than a maximum voltage of a current flowing through the second transistor 6. Therefore, the first transistor 5 may be referred to as a low voltage transistor and the second transistor 6 may be referred to as a high voltage transistor.

The first silicide layer 15 is formed thinner than the first source region 11 on the surface side of the first source region 11. The first silicide layer 15 includes, for example, a nickel platinum silicide layer (NiPtSi layer). For example, the first silicide layer 15 is formed by supplying metal elements such as nickel (Ni) or platinum (Pt) to the first source region 11 and thermally diffusing these metal elements.

The second silicide layer 16 is formed on the surface side of the first drain region 12 and is thinner than the first drain region 12. The second silicide layer 16 includes, for example, a nickel platinum silicide layer (NiPtSi layer). For example, the second silicide layer 16 is formed by supplying metal elements such as nickel (Ni) or platinum (Pt) to the first drain region 12 and thermally diffusing these metal elements. The first silicide layer 15 and the second silicide layer 16 are isolated from each other in the X direction. The first gate insulating film 13 is provided on the bottom surface 7a of the recess portion 7A between the first silicide layer 15 and the second silicide layer 16 spaced apart from each other in the X direction.

The insulating sidewall 19 is formed, for example, by a silicon nitride film or a silicon oxide film. The insulating sidewall 19 is in close contact with the ferroelectric layer 18 on the outside of the ferroelectric layer 18, as seen from the center of the first transistor 5 (the center of the first gate electrode 10), and covers the side of the first gate electrode 10. A bottom portion of the insulating sidewall 19 covers a bottom side of the ferroelectric layer 18, a portion of the first source region 11, and a portion of the first drain region 12. In addition, there is no special restriction on the height in the Z direction of the insulating sidewall 19. The insulating sidewall 19 may be formed to a height to partially or completely cover the side surface of the first gate electrode 10.

In this embodiment, an end in the −X direction side of the first source region 11 reaches a side surface on one side of the device isolation portion 3 near the end, and an end in the +X direction side of the first source region 11 is in contact with an end in the −X direction side of the first gate insulating film 13. An end in the −X direction side of the first drain region 12 is in contact with an end in the +X direction side of the first gate insulating film 13, and an end in the +X direction side of the first drain region 12 reaches a side surface on one side of the device isolation portion 3 near the end.

### Second Transistor

For example, the second transistor 6 includes a second gate electrode 20, the second source region 21, the second drain region 22, the second gate insulating film 23, a third diffusion layer side silicide layer 25 (hereinafter, referred to as a third silicide layer), a fourth diffusion layer side silicide layer 26 (hereinafter, referred to as a fourth silicide layer), a work function metal layer 27, a ferroelectric layer 28, and an insulating sidewall 29. The second source region 21 is an example of the “third diffusion layer region”. The second drain region 22 is an example of the “fourth diffusion layer region”. However, the second drain region 22 may correspond to an example of the “third diffusion layer region”, and the second source region 21 may correspond to an example of the “fourth diffusion layer region”.

The second transistor 6 is provided between the device isolation portions 3 and 3 formed on both sides of the second transistor 6 in the X direction. A recess portion 8A (second recess portion) is formed on the upper surface of the second substrate portion 8 between two device isolation portions 3 adjacent to each other in the X direction. The recess portion 8A is formed such that its bottom surface 8a is one step lower than the upper surface of the device isolation portion 3. An inclined portion 8B, which gradually makes the depth of the recess portion 8A shallow, is formed at a part adjacent to the device isolation portion 3 in the recess portion 8A. A top of the inclined portion 8B is positioned at substantially the same height as an upper surface of the device isolation portion 3, and the top of the inclined portion 8B is continuous with the upper surface of the adjacent device isolation portion 3. A portion where the top of the inclined portion 8B contacts the upper surface of the device isolation portion 3 is an interface position B2 between the surface of the semiconductor substrate 2 and the device isolation portion 3. The recess portion 8A may be described herein as a recess portion including the bottom surface 8a lower than the interface position B2 in the Z direction.

As shown in FIG. 2, the second gate insulating film 23 with a predetermined width in the X direction is disposed on a central side of the bottom surface 8a of the recess portion 8A. The third silicide layer 25 and the fourth silicide layer 26 are positioned on both sides along the X direction. In addition, a third contact electrode 37 connected to the third silicide layer 25 is provided, and a fourth contact electrode 38 connected to the fourth silicide layer 26 is provided.

The second gate electrode 20 is provided on the opposite side of the semiconductor substrate 2 relative to the second gate insulating film 23 to be described below. The second gate electrode 20 is positioned above the bottom surface 8a of the recess portion 8A in the second substrate portion 8. The second gate electrode 20 is positioned between the second source region 21 and the second drain region 22 in the X direction. As an example, the second gate electrode 20 may be formed of a metal such as tungsten, but it may also be a semiconductor layer such as polysilicon or a stacked structure of the semiconductor and the metal layer.

The second source region 21 and the second drain region 22 are formed as part of the bottom surface 8a of the recess portion 8A in the second substrate portion 8. For example, the second source region 21 and the second drain region 22 are formed by doping impurities into the upper portion of the second substrate portion 8 (e.g., the bottom surface 8a and the inclined portion 8B of the recess portion 8A). The second source region 21 and the second drain region 22 are isolated from each other in the X direction.

In this embodiment, each of the second source region 21 and the second drain region 22 includes an n⁻type semiconductor. However, the conductivity type of the second source region 21 and the second drain region 22 is not limited to the example described above and may be the same as the first source region 11 and the first drain region 12.

A depth (depth along the Z direction) of the recess portion 8A is about 1/10 to 2/10 of the maximum depth (maximum depth along the Z direction) of the second source region 21 or the second drain region 22. For example, if the maximum depth of the second source region 21 is about 100 nm, the depth of the recess portion 8A is preferably about 10 to 20 nm.

The second gate insulating film 23 is formed on the bottom surface 8a of the recess portion 8A in the second substrate portion 8. At least a portion of the second gate insulating film 23 is positioned between the second gate electrode 20 and the bottom surface 8a of the second substrate portion 8. The second gate insulating film 23 is formed, for example, by a silicon oxide film. In this embodiment, the thickness of the second gate insulating film 23 in the Z direction is greater than the thickness of the first gate insulating film 13 in the Z direction. The maximum voltage of the current flowing through the second transistor 6 is greater than the maximum voltage of the current flowing through the first transistor 5.

The insulating sidewall 29 is formed, for example, by a silicon nitride film or a silicon oxide film. The insulating sidewall 29 is in close contact with the ferroelectric layer 28 on the outside of the ferroelectric layer 28, as seen from the center of the second transistor 6 (the center of the second gate electrode 20), and covers the side of the second gate electrode 20. A bottom portion of the insulating sidewall 29 covers a bottom side of the ferroelectric layer 28, a portion of the second source region 21, and a portion of the second drain region 22. In addition, there is no special restriction on the height in the Z direction of the insulating sidewall 29. The insulating sidewall 29 may be formed to a height to partially or completely cover the side surfaces of the second gate electrode 20.

In this embodiment, an end in the −X direction side of the second source region 21 reaches a side surface on one side of the device isolation portion 3 near the end, and an end in the +X direction side of the second source region 21 is in contact with an end in the −X direction side of the second gate insulating film 23. An end in the −X direction side of the second drain region 22 is in contact with an end in the +X direction side of the second gate insulating film 23, and an end part in the +X direction side of the second drain region 22 reaches a side surface on one side of the device isolation portion 3 near the end.

As shown in FIG. 2, the semiconductor device 1 includes an insulating layer 31 stacked on the semiconductor substrate 2.

The insulating layer 31 is formed of a silicon oxide film or the like. The insulating layer 31 covers the first transistor 5, the second transistor 6, the device isolation portion 3, the first substrate portion 7, the second substrate portion 8, the third substrate portion 9, and the like.

### Contact Electrode

Next, the contact electrodes are described.

As shown in FIG. 2, the first contact electrode 35 is formed above the first silicide layer 15, extending through the insulating layer 31 in the Z direction and reaching the first silicide layer 15. A lower end of the first contact electrode 35 is electrically connected to the first silicide layer 15. The first contact electrode 35 is connected to the first silicide layer 15 at a connection end 35A thereof.

The second contact electrode 36 is formed above the second silicide layer 16, extending through the insulating layer 31 in the Z direction and reaching the second silicide layer 16. A lower end of the second contact electrode 36 is electrically connected to the second silicide layer 16.

As shown in FIG. 2, the third contact electrode 37 is formed above the third silicide layer 25, extending through the insulating layer 31 in the Z direction and reaching the third silicide layer 25. A lower end of the third contact electrode 37 is electrically connected to the third silicide layer 25. The third contact electrode 37 is connected to the third silicide layer 25 at a connection end 37A thereof.

The fourth contact electrode 38 is formed above the fourth silicide layer 26, extending through the insulating layer 31 in the Z direction and reaching the fourth silicide layer 26. A lower end of the fourth contact electrode 38 is electrically connected to the fourth silicide layer 26.

As shown in FIG. 2, according to the semiconductor device 1 in which the first transistor 5 is formed in the recess portion 7A of the semiconductor substrate 2 and the second transistor 6 is formed in the recess portion 8A of the semiconductor substrate 2, the following effects can be obtained.

When forming the semiconductor device 1, it is necessary to align the mask using a photolithography process, expose required layers at the required positions, and process each layer into a desired shape through etching, etc. However, since the structures of each part of the semiconductor device 1 are miniaturized, it is possible that the formation positions of each element of the semiconductor device 1 may be misaligned due to mask alignment error, etc.

For example, in the semiconductor device 1 with the structure shown in FIGS. 1 and 2, a trench is formed by performing hole processing along the Z direction in the insulating layer 31, metal elements are supplied using the trench, and silicide layers 15, 16, 25, and 26 are formed by thermally diffusing the metal elements. However, if mask alignment errors occur, there is a risk that trenches and the silicide layers 15, 16, 25, and 26 may be formed at positions deviated from the target position.

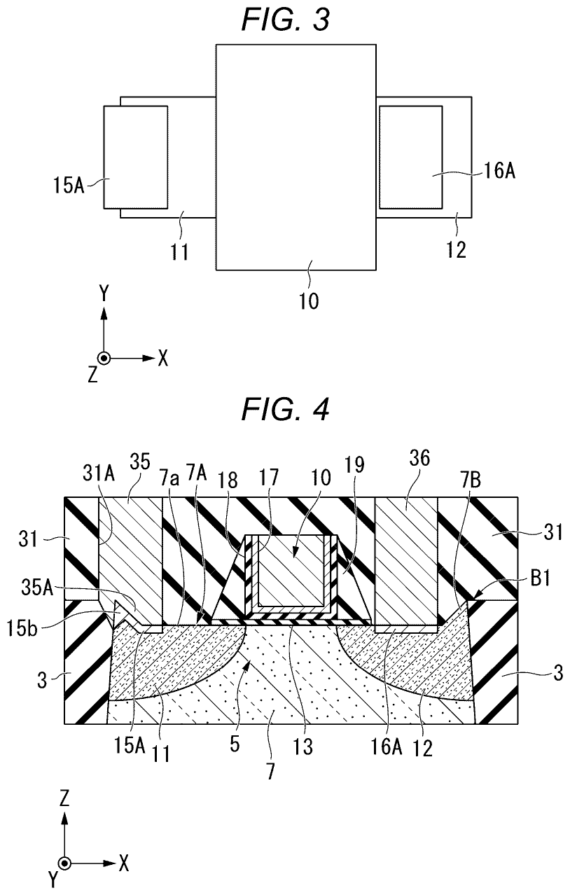

FIGS. 3 and 4 show an example of a state in which the formation positions of a first silicide layer 15A and a second silicide layer 16A are misaligned in the −X direction due to the mask alignment error.

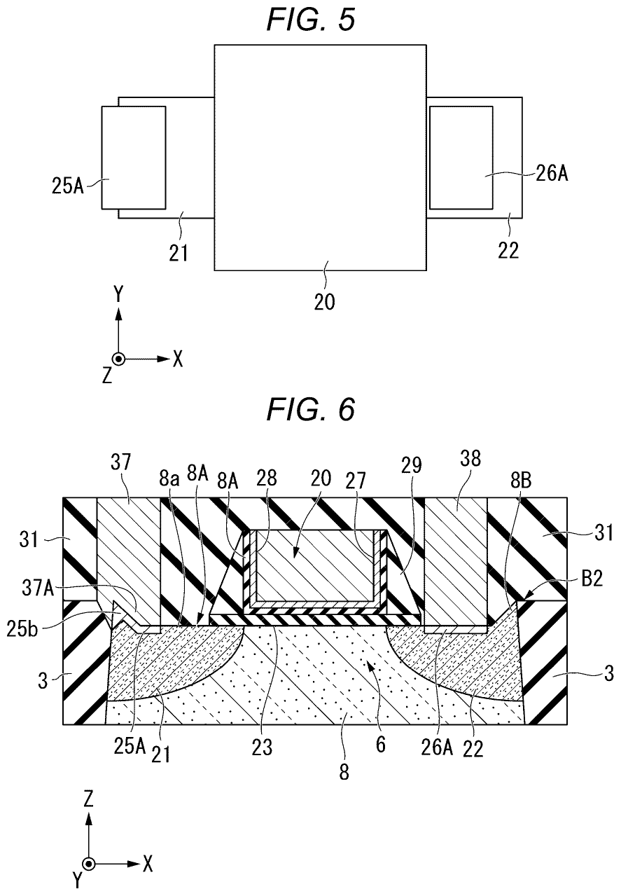

FIGS. 5 and 6 show an example of a state in which the formation positions of a third silicide layer 25A and a fourth silicide layer 26A are misaligned in the −X direction due to the mask alignment error.

When each of the silicide layers 15A, 16A, 25A, and 26A is formed as shown in FIGS. 3 to 6, the first silicide layer 15A and the third silicide layer 25A, which are on the side close to the adjacent device isolation portion 3, may be formed at overlapping positions with the device isolation portion 3.

However, the structure in which the first transistor 5 is formed in the recess portion 7A and the second transistor 6 is formed in the recess portion 8A has superior characteristics compared to the structures of Comparative Examples 1 and 2 to be described below.

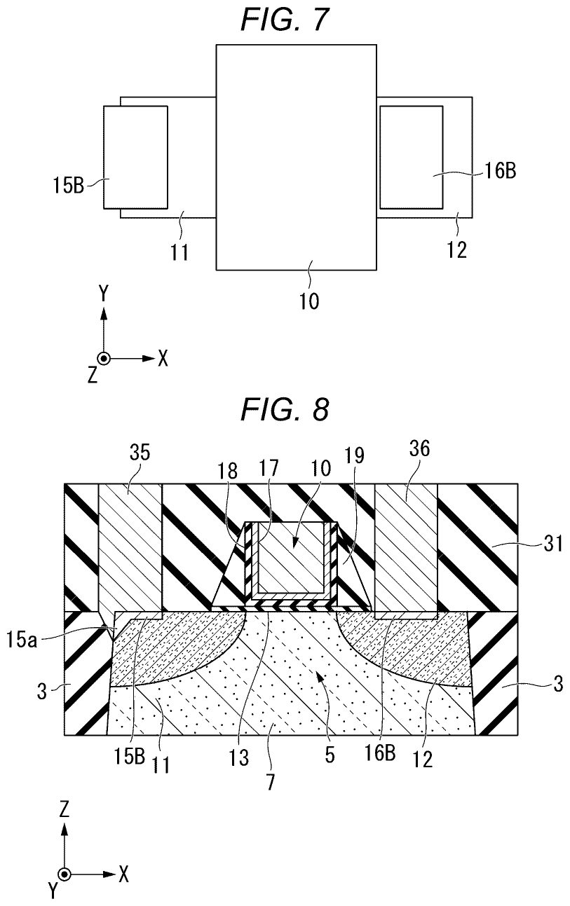

FIGS. 7 and 8 show a structure of Comparative Example 1, in which the first transistor 5 is formed on the upper surface (surface) of the semiconductor substrate 2 without a recess portion provided, and the positions of a first silicide layer 15B and a second silicide layer 16B are misaligned in the −X direction.

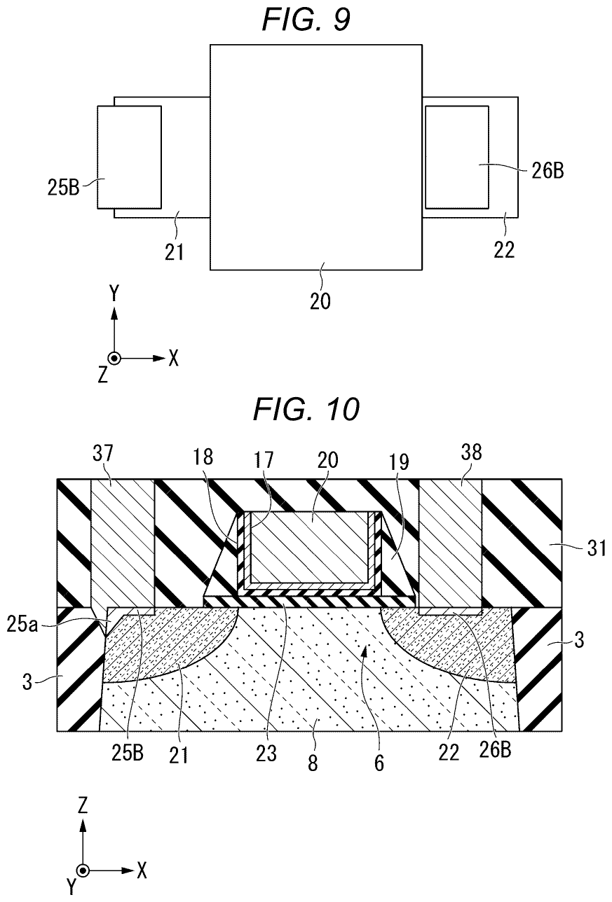

FIGS. 9 and 10 show the structure of Comparative Example 1, in which the second transistor 6 is formed on the upper surface (surface) of the semiconductor substrate 2 without a recess portion provided, and the positions of a third silicide layer 25B and a fourth diffusion layer side silicide layer 26B are misaligned in the −X direction.

In the structure of Comparative Example 1, as shown in FIG. 8, an extension portion 15a extending in the depth direction of the first source region 11 is formed on the side of the first silicide layer 15B close to the device isolation portion 3, in which the position of first silicide layer 15B is misaligned. Likewise, as shown in FIG. 10, an extension portion 25a extending in the depth direction of the second source region 21 is formed on the side of the third silicide layer 25B close to the device isolation portion 3, in which the position of the third silicide layer 25B is misaligned.

In the structure of Comparative Example 1 in which the recess portions 7A and 8A are not formed, the extension portion 15a is formed in the first silicide layer 15B and the extension portion 25a is formed in the third silicide layer 25B for the following reasons.

In the structure in which the first transistor 5 is formed in the recess portion 7A shown in FIG. 2, it is assumed that the trench formed in the insulating layer 31 is misaligned in the −X direction and the misaligned trench is formed as shown in FIG. 4. FIG. 4 shows a trench 31A that is formed when the position of the hole-shaped trench with the first contact electrode 35 formed therein is misaligned.

On a bottom side of the trench 31A, the first silicide layer 15A is deformed, but an extension portion 15b extending upward (toward the +Z direction) is formed. As shown in FIG. 4, the first contact electrode 35 is configured to straddle the top of the device isolation portion 3 and the first silicide layer 15A at the connection end 35A thereof.

The extension portion 15b is formed in the first silicide layer 15A for the following reasons.

If the hole-shaped trench 31A is formed in the insulating layer 31, there are boundary areas between the device isolation portion 3 and the first source region 11, where an edge of the device isolation portion 3 and the inclined portion 7B are present, as can be understood from FIG. 2. The hole-shaped trench 31A is formed by etching the insulating layer 31. Therefore, the trench 31A formed by etching reaches the edge of the device isolation portion 3 and the inclined portion 7B, and even if the edge of the device isolation portion 3 and the inclined portion 7B are somewhat etched, the bottom portion of trench 31A will only be formed to the position shown in FIG. 4 by the end of etching.

In the structure that does not have the recess portion 7A, as shown in FIG. 8, the upper surface (surface) of the first source region 11 and the upper surface (surface) of the device isolation portion 3 are formed flush with each other such that, even if etching is stopped at an ideal timing, the upper surface of the first source region 11 and the upper surface of the device isolation portion 3 will be somewhat etched. As a result, grooves are formed on the upper surface side of the first source region 11 and the upper surface side of the device isolation portion 3 due to etching in the depth direction, and as a result, the extension portion 15a extending in the −Z direction (downward direction) is formed in the first silicide layer 15B.

If the first silicide layer 15B is formed with the extension portion 15a extending in the depth direction as mentioned above, and current is supplied from the first contact electrode 35 to the first transistor 5, the junction leakage current increases. In contrast, the structure shown in FIG. 4 has the characteristic that, compared to the structure shown in FIG. 8, it is able to prevent the increase in junction leakage current, because, although the extension portion 15b is formed in the +Z direction, there is the first source region 11 with a sufficient thickness below the extension portion 15b.

Similarly, in the structure shown in FIG. 6, if the position of the mask is misaligned, an extension portion 25b is formed in the third silicide layer 25A, but due to the presence of the recess portion 8A, the extension portion 25b is formed to extend in the +Z direction (upward direction) compared to the second source region 21. As shown in FIG. 6, the third contact electrode 37 is configured to straddle the top of the device isolation portion 3 and the third silicide layer 25A at the connection end 37A thereof.

In contrast, in a structure that does not have the recess portion 8A, as shown in FIG. 10, the extension portion 25a is formed to extend from the upper surface of the second source region 21 in the −Z direction (downward direction). As a result, the structure shown in FIG. 6 has the characteristic that, compared to the structure shown in FIG. 10, it is able to prevent the increase in junction leakage current, because, although the extension portion 25b is formed in the +Z direction, there is the second source region 21 with a sufficient thickness below the extension portion 25b.

In FIGS. 4 and 6, it is assumed that the first contact electrode 35 and the third contact electrode 37 are misaligned in the −X direction due to the mask misalignment, but it is also possible for the misalignment to occur in the +X direction. If the position is misaligned in the +X direction, the second contact electrode 36 and the fourth contact electrode 38 are also misaligned in the +X direction. In this case, the second contact electrode 36 and the fourth contact electrode 38 overlap with the adjacent device isolation portion 3, resulting in the formation of an extension portion extending in the +Z direction in the second silicide layer 16A and an extension portion extending in the +Z direction in the fourth silicide layer 26A. In this case, the second contact electrode 36 is formed so as to straddle the top of the device isolation portion 3 adjacent to the second silicide layer 16A, and the fourth contact electrode 38 is formed so as to straddle the top of the device isolation portion 3 adjacent to the fourth silicide layer 26A.

In this way, when the position is misaligned in the +X direction, similar effects can be achieved as in the case of misalignment in the −X direction described above.

In the structure of Comparative Example 1 shown in FIGS. 8 and 10, the first silicide layer 15B and the third silicide layer 25B come into contact with the device isolation portion 3 due to the mask misalignment, resulting in the problems described above. In order to avoid this problem, it is conceivable to reduce the size of the first silicide layer 15B and the size of the third silicide layer 25B.

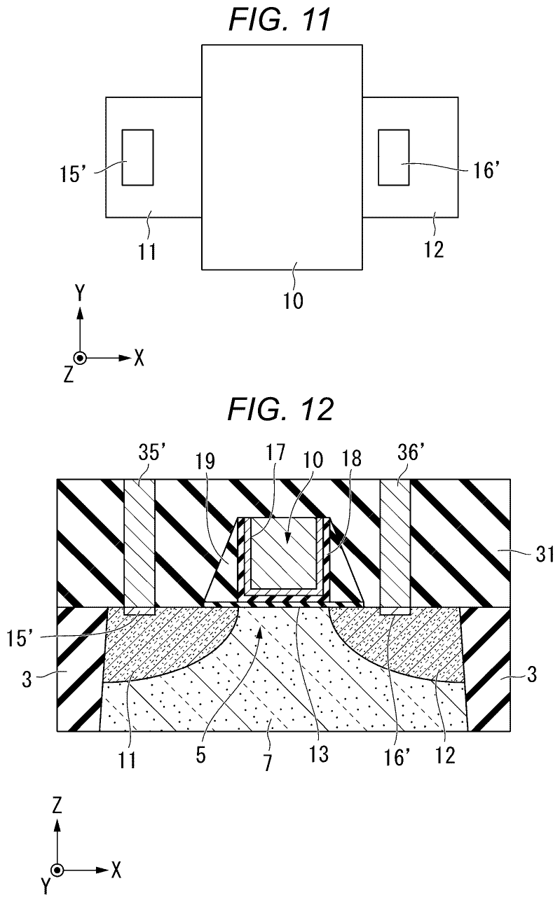

FIGS. 11 and 12 show the structure of Comparative Example 2, which adopts the first transistor 5 configured without a recess portion provided and reduces the sizes of the first silicide layer 15′ in the X and Y directions compared to the first silicide layer 15A shown in FIGS. 3 and 4.

Comparative Example 2 illustrates a case where the size of the first silicide layer 15′ in the X direction is set to about half the size of the first silicide layer 15A in the X direction. Comparative Example 2 illustrates a case where the size of the first silicide layer 15′ in the Y direction is set to about 60% of the size of the first silicide layer 15A in the Y direction. Similarly, in Comparative Example 2, the size of the second silicide layer 16′ is also formed to be smaller, like the first silicide layer 15′.

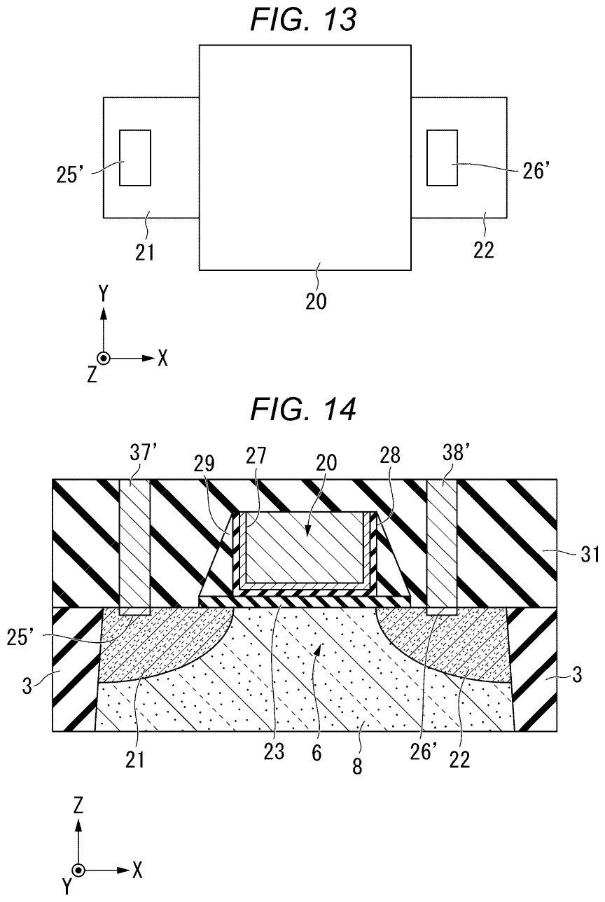

FIGS. 13 and 14 show the structure of Comparative Example 2, which adopts the second transistor 6 configured without a recess portion provided and reduces the sizes of the third silicide layer 25′ in the X and Y directions compared to the third silicide layer 25A shown in FIGS. 5 and 6. Comparative Example 2 illustrates a case where the size of the third silicide layer 25′ in the X direction is set to about half the size of the third silicide layer 25A in the X direction. Comparative Example 2 illustrates a case where the size of the third silicide layer 25′ in the Y direction is set to about 60% of the size of the third silicide layer 25A in the Y direction. Similarly, in Comparative Example 2, the size of the fourth silicide layer 26′ is also formed to be smaller, like the third silicide layer 25′.

By adopting the structure of Comparative Example 2 shown in FIGS. 11 to 14, even if the formation positions of contact electrodes 35′ and 37′ are misaligned due to the mask misalignment, the likelihood of the contact electrodes 35′ and 37′ coming into contact with the adjacent device isolation portion 3 is reduced.

However, as shown in FIGS. 11 and 12, the contact resistance in the first transistor 5 increases because the areas of the first silicide layer 15′ and the second silicide layer 16′ are smaller than the areas of the structure shown in FIGS. 3 and 4. In the structures shown in FIGS. 11 and 12, the on-current of the first transistor 5 is degraded compared to the structure shown in FIGS. 3 and 4.

Based on the above explanation, the structure of the first embodiment shown in FIGS. 3 and 4 has the effect of preventing the increase in junction leakage current compared to the structure of Comparative Example 1, and improving the on-current compared to the structure of Comparative Example 2.

In other words, according to the structure of the first embodiment, even if the mask misalignment occurs, the on-current of both the first transistor 5 (low voltage transistor) and the second transistor (high voltage transistor) 6 can be improved. Furthermore, the semiconductor device 1 can be provided, which can prevent the junction leakage current of both the first transistor 5 and the second transistor even if the mask misalignment occurs.

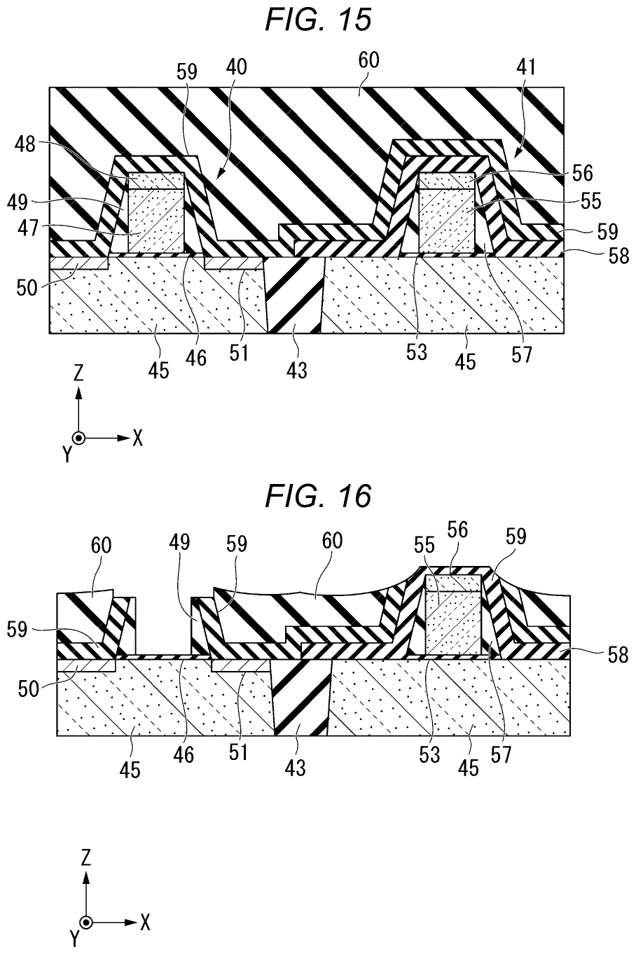

FIG. 15 shows a related transistor structure in which a first transistor 40 and a second transistor 41 are formed adjacent to each other along the X direction of a semiconductor substrate 45 through a device isolation portion 43. In this structure, silicide layers 50 and 51 to be described below are formed on the first transistor 40 side. In FIG. 15, the illustrations of the source region and the drain region formed below the silicide layers 50 and 51 are omitted for brevity.

In the related structure shown in FIG. 15, a dummy gate electrode 47 and an insulating layer 48 made of polysilicon are stacked on a portion of an upper surface of the semiconductor substrate 45 through a gate insulating film 46, with insulating sidewalls 49 formed on both sides of the stack in the X direction. On both sides of the gate insulating film 46 in the X direction, a first diffusion layer side silicide layer 50 and a second diffusion layer side silicide layer 51 are formed on the surface of the semiconductor substrate, resulting in the formation of the first transistor 40. Additionally, a dummy gate electrode 55 and an insulating layer 56 are stacked on an upper surface of the other portion of the semiconductor substrate 45 through a gate insulating film 53, with insulating sidewalls 57 formed on both sides in the X direction of the dummy gate electrode 55 and the insulating layer 56, resulting in the formation of the second transistor 41. In FIG. 15, the illustrations of the source region and the drain region formed in the semiconductor substrate 45 below the dummy gate electrode 55 are omitted for brevity.

In a related structure, when forming the first diffusion layer side silicide layer 50 and the second diffusion layer side silicide layer 51 for the first transistor 40, the dummy gate electrode 55, the insulating layer 56 and the insulating sidewall 57 on the side of the second transistor 41 are covered with a protective film 58 before forming the first diffusion layer side silicide layer 50 and the second diffusion layer side silicide layer 51. Therefore, after the transistors 40 and 41 are formed, a protective film 59 is formed to cover the first transistor 40 and the second transistor 41, and then an insulating layer 60 is formed.

In the case of the related structure shown in FIG. 15, a step difference is inevitably generated between the first transistor 40 and the second transistor 41 due to the presence or absence of the silicide layers 50 and 51. In other words, only the protective film 59 is formed over the first transistor 40, while both the protective film 58 and the protective film 59 are formed above the second transistor 41.

Therefore, as shown in FIG. 16, on the side of the first transistor 40, it is possible to embed a metal gate electrode after removing the dummy gate electrode 47 and the insulating layer 48 with a method such as dry etching, but on the side of the second transistor 41, there was a problem where the polysilicon dummy gate electrode 55 remained without being removed.

In contrast, in the structure shown in FIG. 2, after the formation of the first transistor 5 and the second transistor 6, a hole-shaped trench is formed in the insulating layer 31 and then the silicide layers 15, 16, 25, and 26 are formed. As a result, the problems of the related structures can be solved. In other words, the transistors 5 and 6 adjacent to each other in the X direction through the device isolation portion 3 may be formed with the gate electrodes 10 and 20 of metal while forming the silicide layers 15, 16, 25, and 26 in both the transistors 5 and 6.

### Second Embodiment

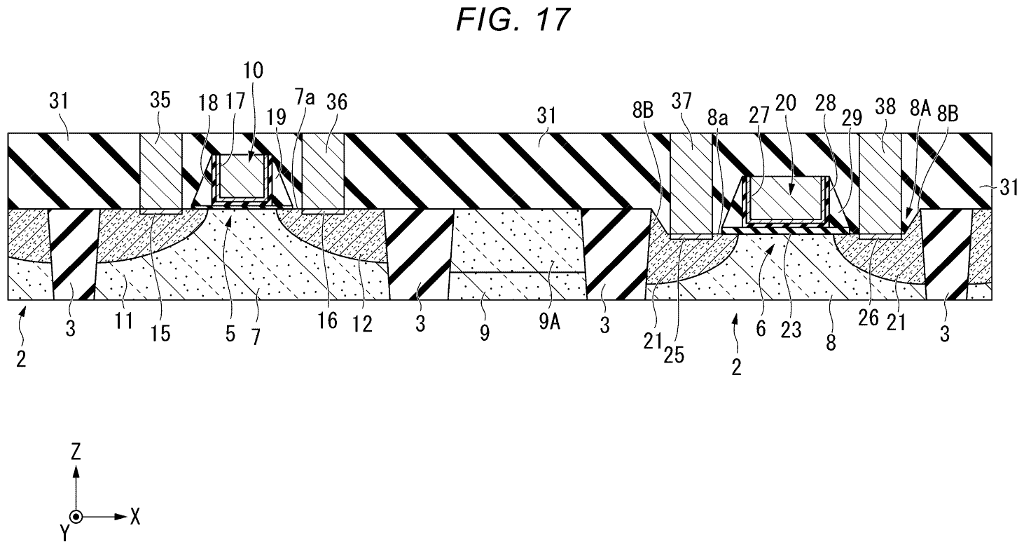

FIG. 17 is a cross-sectional view showing a structure of the first transistor, the second transistor and the semiconductor substrate applied in a semiconductor device of the second embodiment.

In the structure of the second embodiment, components that are equivalent to those in the first embodiment are assigned the same reference numerals and their explanations are omitted or simplified.

In the second embodiment, the recess portion 7A is not formed in the first substrate portion 7 where the first transistor 5 is formed on the semiconductor substrate 2, and the upper surface (surface) of the first substrate portion 7 is aligned with the upper surface of the device isolation portion 3. Accordingly, in the second embodiment, the inclined portion 7B is not formed at a portion where the upper side of the first source region 11 contacts the device isolation portion 3. In the second embodiment, the inclined portion 7B is not formed even at a portion where the upper side of the first drain region 12 contacts the device isolation portion 3.

A difference between the structure of the second embodiment and the structure of the first embodiment is that the recess portion 7A formed on the first substrate portion 7 of the first embodiment is not formed in the second embodiment. As for the other structures, the structure of the second embodiment and the structure of the first embodiment are equivalent to each other.

For example, the structure of the second embodiment is equivalent to the first embodiment in that the recess portion 8A is formed in the second substrate portion 8 where the second transistor 6 (high voltage transistor) is formed, and the structure of the semiconductor substrate 2 where the second transistor 6 is formed is equivalent to that of the first embodiment.

In the structure of the second embodiment, it is possible to reduce the junction leakage current in the second transistor 6, which has a high operating voltage and increased junction leakage current, similarly to the first embodiment. In the second transistor 6, by increasing the size of the silicide layers 25 and 26 compared to the structure in Comparative Example 2, it is possible to reduce the contact resistance, achieving effects equivalent to those in the first embodiment.

In the structure of the second embodiment, the gate insulating film 23 of the second transistor 6 is thicker than the gate insulating film 13 of the first transistor 5. Therefore, if the depth of the recess portion 8A and the thickness of the gate insulating film 23 can be made similar in value, the first transistor 5 and the second transistor 6 may be formed at an equal or approximately equal height position in the Z direction. In this case, the height positions of the gate electrodes 10 and 20 formed in the first transistor 5 and the second transistor 6 may be formed at equal or approximately equal height positions in the Z direction. In this case, the process margin in the etching and deposition processes for forming the gate electrodes 10 and 20 can be increased.

Furthermore, in the second embodiment, the step differences at both ends of the upper portion of the diffusion layer resistance, which may cause variation, can be eliminated, thereby preventing resistance variation in the diffusion layer 9A.

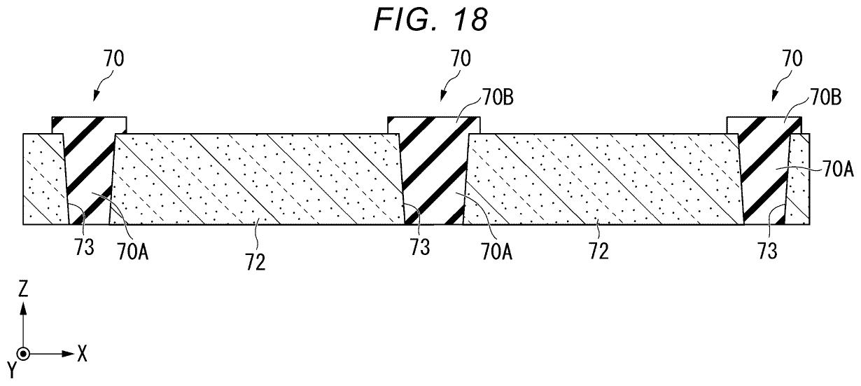

FIGS. 18 to 23 show a method for manufacturing similar structures of the first transistor 5, the second transistor 6 and the semiconductor substrate 2 as applied in the first embodiment.

In the following manufacturing method, the two device isolation portions 3 formed between the first transistor 5 and the second transistor 6 in the first embodiment are simplified and described as one device isolation portion 3, and the manufacturing method for this case will be described.

As shown in FIG. 18, a plurality of device isolation base parts 70 spaced apart from each other by a predetermined distance in the X direction are formed in a semiconductor substrate 72. In order to form a device isolation base part 70, for example, the following process is carried out.

The device isolation base part 70 may be formed by forming a plurality of recessed grooves 73, spaced apart from each other at predetermined intervals in the X direction, in the surface layer side of the semiconductor substrate (silicon substrate) 72, forming an insulating layer that covers the upper surface of the semiconductor substrate 72 with a predetermined thickness while filling these recessed grooves 73, and then removing the insulating layer on the substrate corresponding to the transistor formation region by etching, or the like.

Note that the semiconductor substrate 72 shown in FIGS. 18 to 23 shows only the cross-section of the surface layer part of the semiconductor substrate. As a result of the etching described above, the insulating layer takes on a shape in which a main body 70A fills the recessed groove 73, and a head portion 70B protrudes wider than the recessed groove 73 on the upper surface side of the semiconductor substrate 72. As described above, the device isolation base part 70 is formed on the semiconductor substrate 72.

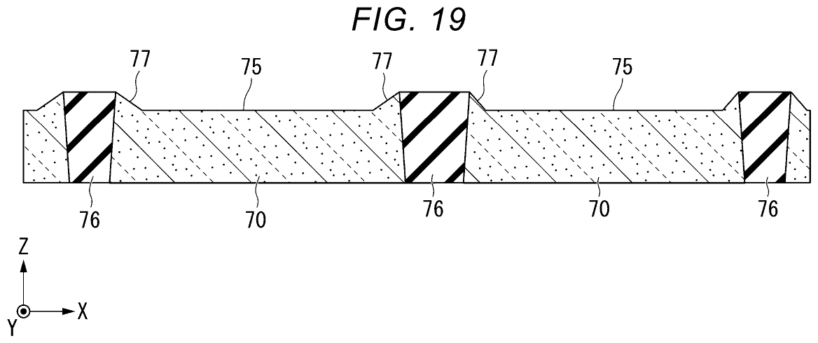

After the device isolation base part 70 is formed, the upper surface of the semiconductor substrate 72 and the device isolation base part 70 are etched, allowing for the etching of the upper surface of the semiconductor substrate 72 to a predetermined depth, thereby forming a recess portion 75 of a predetermined depth shown in FIG. 19, and also removing the head portion 70B of the device isolation base part 70 to form a device isolation portion 76. This etching allows for the formation of the recess portion 75, as well as the formation of an inclined portion 77 made of the constituent material of the semiconductor substrate 72 at the edge of the recess portion 75 and the device isolation portion 76.

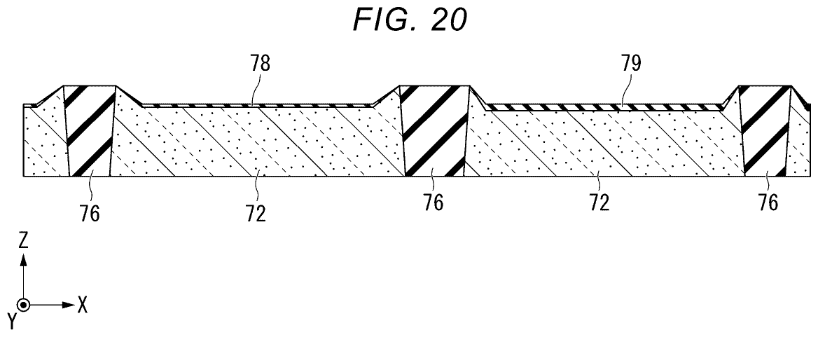

Next, a gate insulating film including a required film thickness is formed by oxidizing the bottom surface side of the recess portion 75 as shown in FIG. 20. In this case, an oxide film 78 with a thin film thickness required for the low voltage transistor is formed in the recess portion 75 corresponding to the region where the first transistor is formed. An oxide film 79 with a thick film thickness required for the high voltage transistor is formed in the recess portion 75 corresponding to the region where the second transistor is formed.

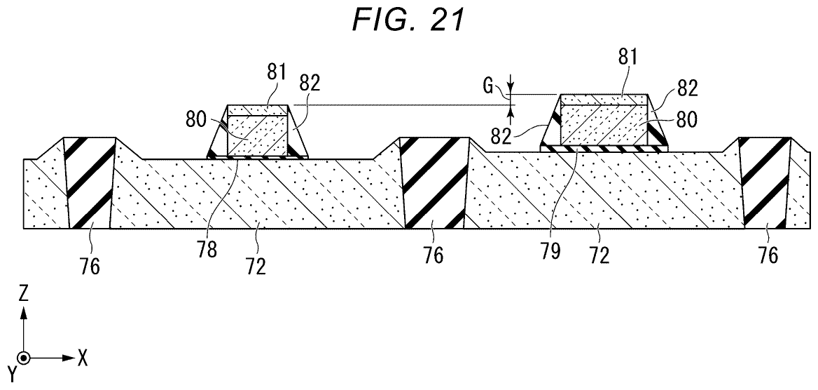

A lower dummy layer 80 formed of dummy polysilicon or the like and an upper dummy layer 81 formed of silicon nitride or the like are formed as shown in FIG. 21, and an insulating sidewall 82 is formed on the X direction side of these dummy layers. In the state shown in FIG. 21, due to a film thickness difference between the oxide film 78 and the oxide film 79, an upper surface height of the upper dummy layer 81 above the oxide film 78 and an upper surface height of the upper dummy layer 81 above the oxide film 79 are different from each other. A height difference shown by an arrow G in the Z direction is generated between one upper dummy layer 81 and the other upper dummy layer 81 spaced apart from each other in the X direction shown in FIG. 21.

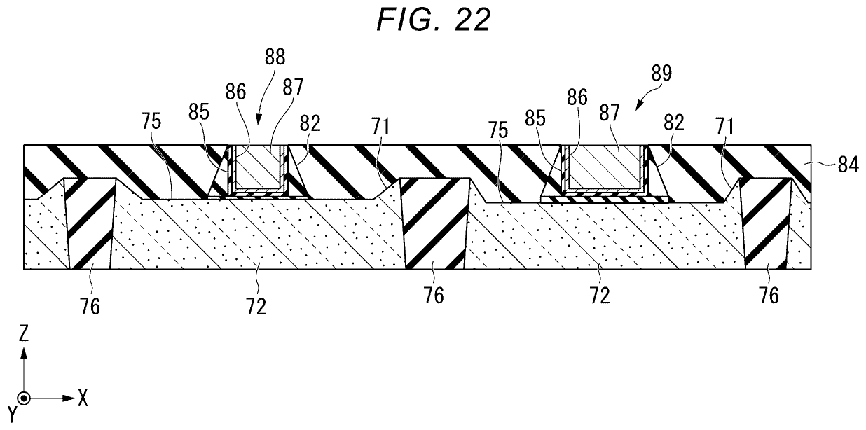

After that, an insulating layer is formed on the semiconductor substrate 72 and the thickness of an insulating layer 84 is aligned with the upper end of the insulating sidewall 82 as shown in FIG. 22 by planar processing such as CMP, and as a result, the upper dummy layer 81 and the lower dummy layer 80 are removed, and a gate electrode 87 is formed by replacing it with a ferroelectric layer 85, a work function metal layer 86, and metal such as tungsten.

Therefore, a first transistor 88 (low voltage transistor) may be formed on the side where the thin oxide film 78 is formed, and a second transistor 89 (high voltage transistor) may be formed on the side where the thick oxide film 79 is formed.

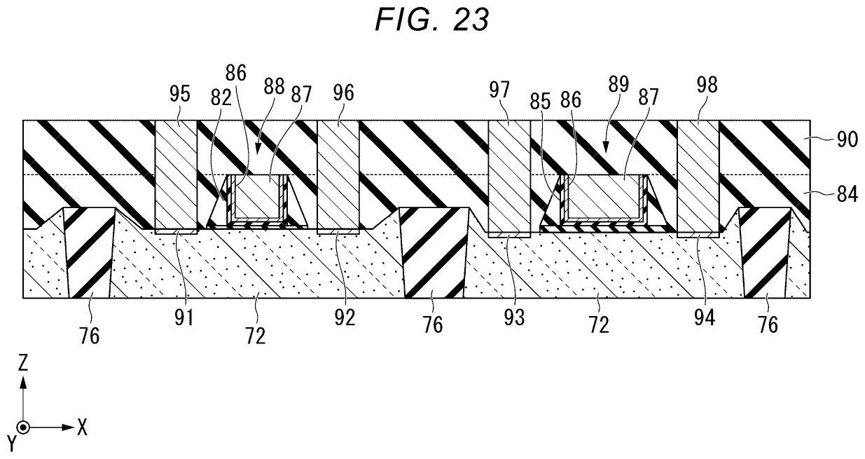

After that, an insulating layer 90 including a required thickness is formed on the insulating layer 84 as shown in FIG. 23, a hole-shaped trench is formed through the insulating layer 84 and the insulating layer 90 in the Z direction to reach the recess portion 75 of the semiconductor substrate 72 on the side of the insulating sidewall 82. After that, metal for forming the silicide layer is filled into the recess portion 75 of the semiconductor substrate 72 from each trench, followed by heat treatment to diffuse the metal and form silicide layers 91, 92, 93, and 94. After that, contact electrodes 95, 96, 97, and 98 are formed to fill each trench.

By the above processes, a stacked structure as shown in FIG. 23 can be obtained. The stacked structure shown in FIG. 23 differs from the stacked structure shown in FIG. 2 only in that there are two device isolation portions 3 present between the first transistor 5 and the second transistor 6, or only one, and all other structures are equivalent.

In the first embodiment, the first transistor 5 is provided on the first substrate portion 7 which includes the recess portion 7A, and the second transistor 6 is provided on the second substrate portion 8 which includes the recess portion 8A. In the second embodiment, the first transistor 5 is provided on the first substrate portion 7 which does not include the recess portion 7A, and the second transistor 6 is provided on the second substrate portion 8 which includes the recess portion 8A. In contrast, it is also possible to adopt a configuration where the first transistor 5 is provided on the first substrate portion 7 which includes the recess portion 7A, and the second transistor 6 is provided on the second substrate portion 8 which does not include the recess portion 8A. Furthermore, the semiconductor substrate 2 may be provided with a plurality of first transistors 5 and a plurality of second transistors 6, it is possible to form all first transistors 5 in the recess portion 7A and all second transistors 6 in the recess portion 8A, but aspects are not limited thereto. For example, it is possible to form the recess portion 7A corresponding to some of the first transistors 5, while forming the first transistor 5 on the first substrate portion 7 that does not include the recess portion 7A. For example, it is possible to form the recess portion 8A corresponding to some of the second transistors 6, while forming the second transistor 6 on the second substrate portion 8 that does not include the recess portion 8A.

Furthermore, the first embodiment shown in FIG. 2 and the second embodiment shown in FIG. 17 illustrate the first transistor 5 and the second transistor 6 adjacent to each other in the X direction through the device isolation portion 3. However, the first transistor 5 and the second transistor 6 provided on the semiconductor substrate 2 and adjacent to each other in the X direction is only one example, and for example, it goes without saying that the above embodiments can be applied to a structure in which the plurality of first transistors 5 are adjacent to each other through a plurality of device isolation portions 3 and the plurality of second transistors 6 are adjacent to each other through a plurality of device isolation portions 3.

One of the purposes of providing the recess portions 7A and 8A for the first transistor 5 and the second transistor 6 is to eliminate defects that may occur when the position of the contact electrode is misaligned due to the mask alignment error, or the like. Therefore, if the spacing between the first transistor 5 formed on the semiconductor substrate 2 and the adjacent device isolation portion 3 or the spacing between the second transistor 6 and the adjacent device isolation portion 3 is sufficiently larger than the misalignment errors, the first transistor 5 or the second transistor 6 may be provided without forming the recess portion 7A or 8A. Therefore, it is possible to select the first transistor 5 or the second transistor 6, which has a high integration density and a small spacing with the adjacent device isolation portion 3, and apply the structure described in the previous embodiments.

While certain embodiments have been described, these embodiments have been presented by way of example only, and are not intended to limit the scope of the disclosure.

Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor substrate;
a first transistor including:
a first diffusion layer region and a second diffusion layer region provided on the semiconductor substrate;
a first gate insulating film provided on the semiconductor substrate, and including at least a portion facing a region between the first diffusion layer region and the second diffusion layer region;
a first gate electrode positioned over the first gate insulating film; and
a first silicide layer embedded in an upper surface of the first diffusion layer region and a second silicide layer embedded in an upper surface of the second diffusion layer region;
a second transistor including:
a third diffusion layer region and a fourth diffusion layer region provided on the semiconductor substrate;
a second gate insulating film provided on the semiconductor substrate, and including at least a portion facing a region between the third diffusion layer region and the fourth diffusion layer region;
a second gate electrode positioned over the second gate insulating film; and
a third silicide layer embedded in an upper surface of the third diffusion layer region and a fourth silicide layer embedded in an upper surface of the fourth diffusion layer region; and
a device isolation portion embedded in the semiconductor substrate to isolate the first transistor and the second transistor from their respective surrounding regions, wherein
at least one of the first transistor or the second transistor is formed in a recess portion that has a bottom surface at a position lower than an upper surface of the device isolation portion.

2. The semiconductor device according to claim 1, wherein
the first gate insulating film is thinner than the second gate insulating film,
the first transistor is a low voltage transistor, and
the second transistor is a high voltage transistor.

3. The semiconductor device according to claim 1, wherein
the first silicide layer and the second silicide layer are formed in a first recess portion where the first transistor is formed, and the third silicide layer and the fourth silicide layer are formed in a second recess portion where the second transistor is formed.

4. The semiconductor device according to claim 1, wherein
the first transistor is formed in a first recess portion that has a bottom surface at a position lower than the upper surface of the device isolation portion, and
the second transistor is formed in a second recess portion that has a bottom surface at a position lower than the upper surface of the device isolation portion.

5. The semiconductor device according to claim 1, wherein
the first gate insulating film is thinner than the second gate insulating film, the first transistor is a low voltage transistor, and the second transistor is a high voltage transistor,
the second transistor is formed in a recess portion that has a bottom surface at a position lower than the upper surface of the device isolation portion, and
the first transistor is formed on a surface of the semiconductor substrate at a same height as the upper surface of the device isolation portion.

6. The semiconductor device according to claim 1, comprising:
an insulating layer covering the semiconductor substrate and the device isolation portion;
a first contact electrode formed through the insulating layer in a thickness direction to be connected to the first silicide layer;
a second contact electrode formed through the insulating layer in a thickness direction to be connected to the second silicide layer;
a third contact electrode formed through the insulating layer in a thickness direction to be connected to the third silicide layer; and
a fourth contact electrode formed through the insulating layer in a thickness direction to be connected to the fourth silicide layer.

7. The semiconductor device according to claim 1, comprising:
an insulating layer covering the semiconductor substrate and the device isolation portion;
a first contact electrode formed through the insulating layer in a thickness direction to be connected to the first silicide layer;
a second contact electrode formed through the insulating layer in a thickness direction to be connected to the second silicide layer;
a third contact electrode formed through the insulating layer in a thickness direction to be connected to the third silicide layer; and
a fourth contact electrode formed through the insulating layer in a thickness direction to be connected to the fourth silicide layer, wherein
at least a portion of a connection end of at least one of the first contact electrode, the second contact electrode, the third contact electrode and the fourth contact electrode is connected to straddle any silicide layer adjacent to the connection end and the device isolation portion adjacent to the any silicide layer.

8. A method, comprising:
forming a first recess portion and a second recess portion that respectively have bottom surfaces lower than an upper surface of a plurality of device isolation portions formed in a semiconductor substrate;
forming a first transistor in the first recess portion, wherein the first transistor includes:
a first diffusion layer region and a second diffusion layer region provided on the semiconductor substrate;
a first gate insulating film provided on the semiconductor substrate, and including at least a portion facing a region between the first diffusion layer region and the second diffusion layer region;
a first gate electrode positioned over the first gate insulating film; and
a first silicide layer embedded in an upper surface of the first diffusion layer region and a second silicide layer embedded in an upper surface of the second diffusion layer region; and
forming a second transistor in the second recess portion, wherein the second transistor includes:
a third diffusion layer region and a fourth diffusion layer region provided on the semiconductor substrate;
a second gate insulating film provided on the semiconductor substrate, and including at least a portion facing a region between the third diffusion layer region and the fourth diffusion layer region;
a second gate electrode positioned over the second gate insulating film; and
a third silicide layer embedded in an upper surface of the third diffusion layer region and a fourth silicide layer embedded in an upper surface of the fourth diffusion layer region.

9. The method according to claim 8, wherein
the first gate insulating film is thinner than the second gate insulating film,
the first transistor is a low voltage transistor, and
the second transistor is a high voltage transistor.
